(19) United States
(12) Patent Application Publication
(10) Pub. No.: US 2012/0033362 A1
(43) Pub. Date: Feb. 9, 2012

(54) FLAT-PANEL DISPLAY MONITOR

(75) Inventor: ZHEN-XING YE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/036,150

(22) Filed: Feb. 28, 2011

(30) Foreign Application Priority Data
Aug. 3, 2010 (CN) 201010244192.2

(51) Int. Cl. H05K 7/00

(52) U.S. Cl. 361/679.01

(57) ABSTRACT

A flat-panel display monitor includes a display, a support stand, a fixing member, a mounting member, an elevating support mechanism, and a connecting member. The elevating support mechanism includes a first link bar, a second link bar, at least one third link bracket, and at least one fourth link bracket. The first link bar are hinged with the at least one third link bracket and the at least one fourth link bracket. The second link bar are hinged with the at least one third link bracket and the at least one fourth link bracket. The connecting member is rotatably connected to the support stand. The at least one third link bracket is fixed to the connecting member. The connecting member and the fixing member are fixed to the elevating support mechanism. The fixing member is rotatably connected to the mounting member, and the display is mounted onto the mounting member.

### BACKGROUND

1. Technical Field

The present disclosure relates to flat-panel display monitors, and more particularly to a flat-panel display having a support stand and an elevating support mechanism having adjustable angles and height.

2. Description of Related Art

Flat-panel display monitors often employ an elevating support mechanism to connect a support stand and a display, such that the viewing angle and the height of the display can be adjusted without moving the support stand.

However, this adjustment cannot alter the angle of the display relative to the user. To share the display between users, the support stand must be moved correspondingly, which is an inconvenient requirement.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is an assembled, isometric view of one embodiment of a flat-panel display monitor including a support stand, a connecting member, an elevating support mechanism, a fixing member, a mounting member, and a display.

FIG. 2 is similar to FIG. 1, but viewed from another aspect.

FIG. 3 is an exploded, isometric view of the supporting member, the connecting member, the elevating support mechanism, the fixing member, and the mounting member of FIG. 1.

FIG. 4 is similar to FIG. 3, but viewed from another aspect.

### DETAILED DESCRIPTION

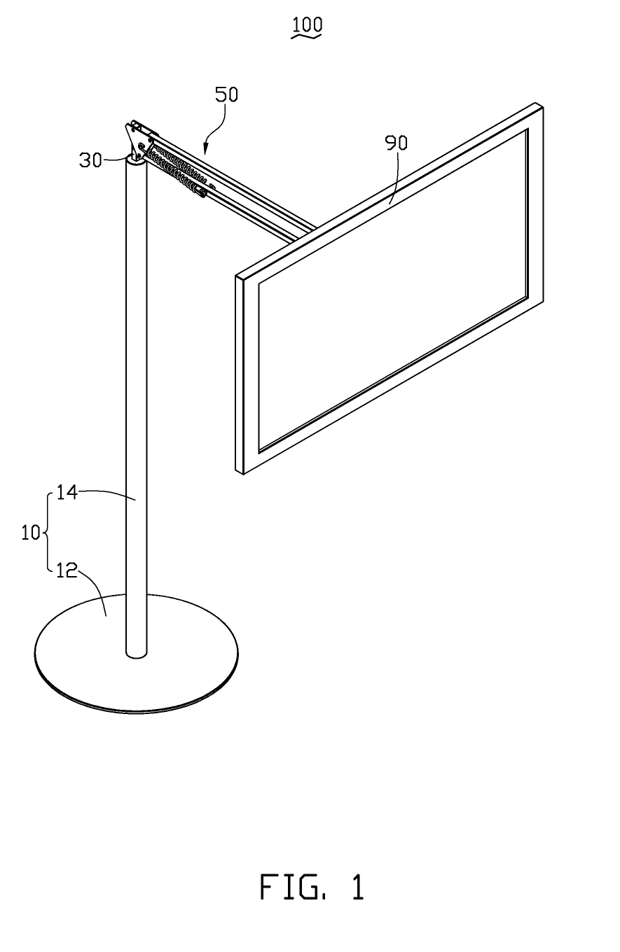

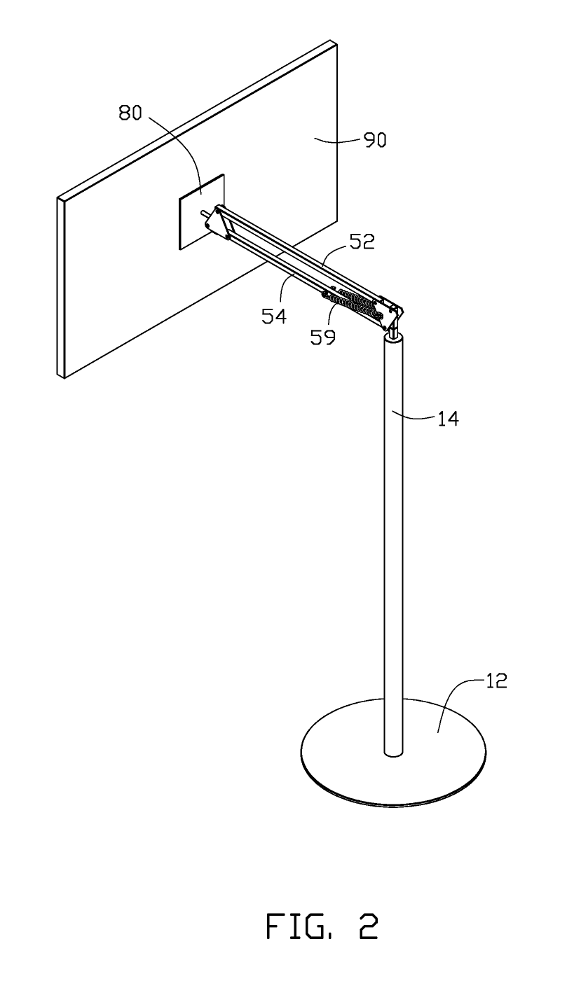

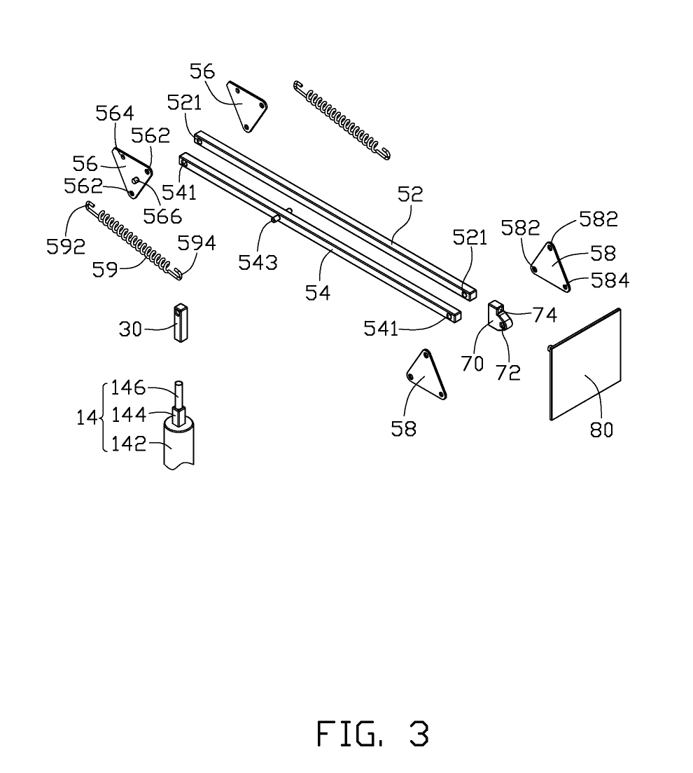

Referring to FIGS. 1 through 3, an embodiment of a flat-panel display monitor 100 includes a support stand 10, a connecting member 30, an elevating support mechanism 50, a fixing member 70 (not shown in FIGS. 1 and 2), a mounting member 80, and a display 90. The connecting member 30 is rotatably connected to the support stand 10. The connecting member 30 and the fixing member 70 are fixed to the elevating support mechanism 50, respectively. The fixing member 70 is rotatably connected to the mounting member 80. The display 90 is mounted onto the mounting member 80.

The support stand 10 includes a base 12 and a supporting member 14. In the illustrated embodiment, the base 12 is substantially a circular plate. The supporting member 14 includes a main body 142, a resisting portion 144 and a rotary portion 146. The main body 142 is substantially cylindrical, and extends from a middle portion of the base 12. The resisting portion 144 is substantially rectangular, and extends from an end of the main body 142 away from the base 12. The rotary portion 146 is substantially cylindrical, and extends from an end of the resisting portion 144 away from the main body 142.

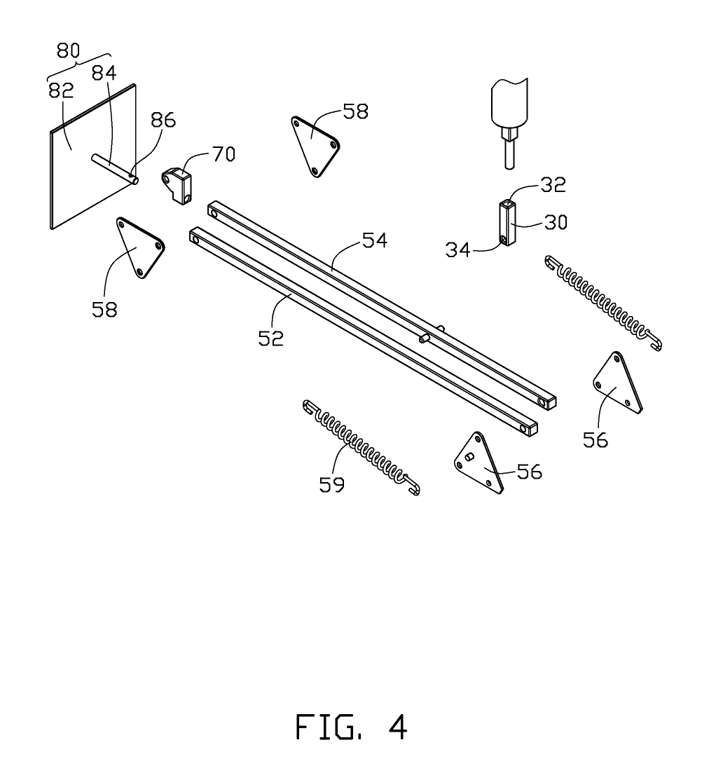

Referring also to FIG. 4, the connecting member 30 is substantially a rectangular rod, and defines a shaft hole 32 corresponding to the rotary portion 146, and a through hole 34. Axis of the through hole 34 is substantially perpendicular to the axis of the shaft hole 32.

The elevating support mechanism 50 includes a first link bar 52, a second link bar 54, a pair of third link brackets 56, a pair of fourth link brackets 58, and a pair of adjustable positioning members 59.

The first link bar 52 is substantially a rod with a square cross section. Each end of the first link bar 52 defines a hinged hole 521. Axis of each hinged hole 521 is substantially perpendicular to a length direction of the first link bar 52. Shape and length of the second link bar 54 are the same as that of the first link bar 52. Each end of the second link bar 54 defines a hinged hole 541. The second link bar 54 forms at least one connecting portion 543 at the middle portion thereof. In the illustrated embodiment, the second link bar 54 forms a pair of connecting portions 543; the connecting portions 543 are a plurality of protrusions which protrude from two opposite side surfaces of the second link bar 54. It should be pointed out that the connecting portion 543 is not limited to a protrusion, and may alternatively be a hook or latching groove.

The third link bracket 56 is substantially a triangular plate. Each third link bracket 56 defines two hinged holes 562 and a connecting hole 564. Two hinged holes 562 are defined at two corners of the third link bracket 56 respectively. The connecting hole 564 is defined at the other remaining corner of the third link bracket 56. Each third link bracket 56 includes a latching portion 566. In the illustrated embodiment, the latching portion 566 is a protrusion extending from the middle portion of the third link bracket 56. It should be pointed out that the latching portion 566 is not limited to a protrusion, and may alternatively be a hook or latching groove.

The fourth link bracket 58 is substantially a triangular plate. Each of the fourth link brackets 58 defines two hinged holes 582 and a fixing hole 584. Two hinged holes 582 are defined at two corners of the fourth link bracket 58 respectively. The fixing hole 584 is defined at the other remaining corner of the fourth link bracket 58.

Each adjustable positioning member 59 includes a first locking portion 592 and a second locking portion 594. The first locking portion 592 and the second locking portion 594 are formed at two opposite ends of the adjustable positioning member 59 respectively. In the illustrated embodiment, the adjustable positioning member 59 is a spring, and the first locking portion 592 and the second locking portion 594 are a plurality of hooks. It should be pointed out that the adjustable positioning member 59 is not limited to a spring, and may alternatively be a telescopic rod, as long as the adjustable positioning member 59 has an adjustable length.

The fixing member 70 is substantially a block, and defines a receiving hole 72 and a pivot hole 74. The receiving hole 72 and the pivot hole 74 are both through holes. Axis of the receiving hole 72 is substantially perpendicular to the axis of the pivot hole 74.

The mounting member 80 includes a mounting portion 82 and a rotation shaft 84. The mounting portion 82 is substantially a rectangular plate. The rotation shaft 84 extends from a middle portion of the mounting portion 82. The rotation shaft 84 defines a pin hole 86 at an end at the side thereof away from the mounting portion 82.

During assembly, a shaft (not shown) passes through the hinged hole 562 defined at a corner of one of the third link brackets 56, the hinged hole 521 defined at one end of the first link bar 52, and the hinged hole 562 defined at a corner of the other third link bracket 56 in that order, such that one end of the first link bar 52 is hinged with and positioned between two third link brackets 56. The other end of the first link bar 52 is hinged with one corner of each fourth link bracket 58 defining the hinged hole 582, one end of the second link bar 54 is hinged with another corner of another third link bracket 56 defining the hinged hole 562, and the other end of the second link bracket 54 is hinged with another corner of one fourth link bracket 58 defining the hinged hole 582, in the same way. The first link bar 52 and the second link bar 54 are spaced apart and parallel to each other. The first locking portion 592 and the second locking portion 594 of each adjustable positioning member 59 are latched with one of the connecting portions 543 and one of the latching portions 566.

A fastener (not shown) passes through the connecting hole 564 of one of the third link bracket 56, the through hole 34 of the connecting member 30, and the connecting hole 564 of the other third link bracket 56, such that the connecting member 30 is securely positioned between the two third link brackets 56. The fixing member 70 is securely positioned between the two fourth link brackets 58 in the same way. The rotary portion 146 is received in the shaft hole 32 of the connecting member 30, and an end of the connecting member 30 defining the shaft hole 32 resists the resisting portion 144 of the supporting member 14. The rotation shaft 84 passes through the pivot hole 74, and a pin (not shown) is received in the pin hole 86. The display 90 is mounted on the mounting portion 82 of the mounting member 80.

When the height of the display 90 is to be adjusted, external force elevates or depresses the display 90, and the first link bar 52 and the second link bar 54 rotate relative to the third link brackets 56 and the fourth link brackets 58, whereby a plurality of angles of the first link bracket 52 and the second link bracket 54 relative to the third link bracket 56 and the fourth link bracket 58 are changed, such that the height of the display 90 is adjusted. The positions of the third link brackets 56 fixed to the connecting member 30 are fixed, and the angles of the third link brackets 56 and the fourth link brackets 58 relative to the gravity direction remain unchanged, and the viewing angle of the display is not changed. Adjustment of the angle of the display 90 relative to the user requires only an external force applied on the display 90 whereby the connecting member 30 rotates relative to the rotary portion 146, and the display 90 and the elevating support mechanism 50 rotate relative to the support stand 10.

Two ends of each adjustable positioning member 59 are connected to the second link bar 54 and one of the third link bracket 56, and a triangular configuration is formed by the adjustable positioning member 59, the second link bar 54, and the third link bracket 56, thereby stably maintaining the display 90 in a desired position.

The rotation shaft 84 is rotatably received in the pivot hole 74 of the fixing member 70, such that the display 90 is capable of rotating relative to the axis of the pivot hole 74, thus allowing the display 90 to be positioned on two axes.

The third link brackets 56 and the fourth link brackets 58 are triangular plates, and can be formed by punching. The flat-panel display monitor 100 employs only a few members, thus simplifying the structure and, accordingly, manufacture and assembly, while lowering costs.

The adjustable positioning member 59 may be omitted, whereby a plurality of resilient members and friction members may keep or maintain the elevating support mechanism 50 in a desired position. The connecting member 30 may be hinged with one of the third link brackets 56, and the fixing member 70 may be hinged with one of the fourth link brackets 58.

Alternatively, the flat-panel display monitor 100 may employ only one third link bracket 56 and one fourth link bracket 58. The third link bracket 56 and the fourth link bracket 58 are not limited to triangular plates, and they may be rods alternatively, as long as the connecting hole 564 and the fixing hole 584 are defined at the middle portions of the third link bracket 56 and the fourth link bracket 58.

It is believed that the present embodiments and their advantages will be understood from the foregoing description, and it will be apparent that various changes may be made thereto without departing from the spirit and scope of the disclosure or sacrificing all of its material advantages.

What is claimed is:

1. A flat-panel display monitor, comprising:
a display;
a support stand;
a fixing member;
a mounting member;
an elevating support mechanism, the elevating support mechanism comprising a first link bar, a second link bar, at least one third link bracket, and at least one fourth link bracket; and
a connecting member, wherein two ends of the first link bar are hinged with the at least one third link bracket and the at least one fourth link bracket, respectively, the second link bar is parallel to the first link bar, two ends of the second link bar are hinged with the at least one third link bracket and the at least one fourth link bracket, the connecting member is rotatably connected to the support stand, the at least one third link bracket is fixed to the connecting member, the connecting member and the fixing member are fixed to the elevating support mechanism, respectively; the fixing member is rotatably connected to the mounting member, and the display is mounted onto the mounting member.

2. The flat-panel display monitor of claim 1, wherein the elevating support mechanism further comprises at least one adjustable positioning member, the at least one adjustable positioning member has an adjustable length, and two ends of the at least one adjustable positioning member are connected to the second link bracket and the at least one third link bracket, respectively.

3. The flat-panel display monitor of claim 1, wherein the at least one adjustable positioning member is a spring.

4. The flat-panel display monitor of claim 1, wherein the at least one third link bracket is a triangular plate, the first link bar and the second link bar are hinged with two corners of the at least one third link bracket, and the connecting member is fixed to the other corner of the at least one third link bracket.

5. The flat-panel display monitor of claim 1, wherein the fixing member is fixed to the at least one fourth link bracket.

6. The flat-panel display monitor of claim 5, wherein a rotation axis of the display is perpendicular to a rotation axis of the connecting member.

7. The flat-panel display monitor of claim 5, wherein the at least one fourth link bracket is a triangular plate, the first link bar and the second link bar are hinged with two corners of the at least one fourth link bracket, and the fixing member is fixed to the another corner of the at least one third link bracket.

8. The flat-panel display monitor of claim 1, wherein the support stand comprises a base and a supporting member extending from the base, the supporting member forms a rotary portion at an end of the supporting member away from the base, and the connecting member defines a shaft hole corresponding to the rotary portion.

9. The flat-panel display monitor of claim 8, wherein the supporting member further comprises a main body and a resisting portion, the main body extends from the base, the resisting portion extends from an end of the main body away from the base and abuts the connecting member, and the rotary portion extends from the resisting portion away from the main body.

10. A flat-panel display monitor, comprising:
a display;
a support stand;
a fixing member;
a mounting member;
an elevating support mechanism, the elevating support mechanism comprising a first link bar, a second link bar, two third link brackets, and two fourth link brackets; and
a connecting member, wherein two ends of the first link bar are positioned between and hinged with the two third link brackets and the two fourth link brackets, respectively, the second link bar is parallel to the first link bar, two ends of the second link bar are positioned between and hinged with the two third link brackets and the two fourth link brackets, respectively, the connecting member is rotatably connected to the support stand, the connecting member is positioned between and fixed to the two third link bracket, the connecting member and the fixing member are fixed to the elevating support mechanism, respectively; the fixing member is rotatably connected to the mounting member, and the display is mounted onto the mounting member.

11. The flat-panel display monitor of claim 10, further comprising a fixing member, wherein the fixing member is positioned between and fixed to the at least one fourth link bracket.

12. The flat-panel display monitor of claim 11, wherein the rotation axis of the mounting member is perpendicular to the rotation axis of the connecting member.
